(19) United States
(12) Patent Application Publication
(10) Pub. No.: US 2020/0033067 A1
(43) Pub. Date: Jan. 30, 2020

(54) HEAT SINK AND COOLING DEVICE USING THE SAME

(71) Applicant: TAIWAN MICROLOOPS CORP., New Taipei City (TW)

(72) Inventors: Chun-Hung LIN, New Taipei City (TW); Chih-Wei WANG, New Taipei City (TW)

(21) Appl. No.: 16/045,704

(22) Filed: Jul. 25, 2018

(51) Int. Cl. F28D 15/02; H05K 7/20

(52) U.S. Cl. CPC F28D 15/0275; H05K 7/2039; H05K 7/20336

(57) ABSTRACT

A heat sink and a cooling device using the heat sink is provided. The heat sink includes a heat pipe, a first fin module and a second fin module. The heat pipe includes a pipe body, a capillary structure and a working fluid and has a heat receiving section, a first heat discharge section and a second heat discharge section. The interior of the heat receiving section has a heat receiving chamber; the interior of the first heat discharge section and the second heat discharge section has a heat discharge chamber; and the heat receiving chamber has a cross-sectional area greater than that of the heat discharge chamber. The first and second fin modules are sheathed and thermally contacted with the first and second heat discharge sections respectively. The working fluid may flow into each heat discharge chamber for heat exchange to improve the thermal conduction and dissipation.

### FIELD OF THE INVENTION

This disclosure relates to a heat sink technology, and more particularly to a heat sink and a cooling device using the heat sink.

### BACKGROUND OF THE INVENTION

As the computing speed of electronic devices increases constantly, the heat generated by the electronic devices is also getting higher and higher. To effectively overcome the issue of high heat, related manufacturers have used a wide range of applications of heat pipes with good thermal conductivity. In particular, a heat sink formed by combining a heat pipe and a cooling fin module and having the features of lightweight and good conduction and thermal dissipation has become an indispensable part for the heat dissipation of electronic devices.

In general, a conventional heat sink comprises a heat pipe and a cooling fin module, wherein a heat receiving section and a heat discharge section of most heat pipes are manufactured with the same diameters. When a vaporized working fluid flows from the heat receiving end to the heat discharge end, the working fluid can just conduct heat by a pressure difference caused by a temperature change of the working fluid. Therefore, the thermal conduction performance of the working fluid is limited substantially. Some of the heat pipes just come with a single heat receiving section and a single heat discharge section, and thus the thermal conduction performance of the heat pipe is poor.

In view of the aforementioned drawbacks of the prior art, the discloser of this disclosure based on years of experience to conduct extensive research and experiment, and finally provided a feasible solution to overcome the drawbacks of the prior art.

### SUMMARY OF THE INVENTION

Therefore, it is a primary objective of this disclosure to provide a heat sink and a cooling device using the heat sink, wherein a heat receiving chamber and each heat discharge chamber have different cross-sectional areas, so that a vaporized working fluid can flow to each heat discharge chamber for heat exchanges more quickly to improve the thermal conduction and dissipation effects of the heat sink.

To achieve the aforementioned and other objectives, this disclosure provides a heat sink comprising a pipe body, a capillary structure, and a working fluid filled in the pipe body, wherein the heat pipe includes a heat receiving section, a first heat discharge section and a second heat discharge section extending from both ends of the heat receiving section respectively, a heat receiving chamber formed inside the heat receiving section, and a heat discharge chamber formed inside the first heat discharge section and the second heat discharge section separately, and the heat receiving chamber has a cross-sectional area greater than the cross-sectional area of each of the heat discharge chambers; a first fin module, socketed to and thermally contacted with the first heat discharge section; and a second fin module, socketed to and thermally contacted with the second heat discharge section.

To achieve the aforementioned and other objectives, this disclosure provides a cooling device comprising a thermal conduction base; and a heat sink, comprising a heat pipe, a first fin module and a second fin module, wherein the heat pipe includes a pipe body and a capillary structure and a working fluid disposed inside the pipe body, and the heat pipe has a heat receiving section, and a first heat discharge section and a second heat discharge section extending from both ends of the heat receiving section respectively, and the heat receiving section is disposed on the thermal conduction base, and the heat receiving section has a heat receiving chamber therein, and the first heat discharge section and the second heat discharge section have a heat discharge chamber disposed therein separately, and the heat receiving chamber has a cross-sectional area greater than the cross-sectional area of each of the heat discharge chambers; and the first fin module is socketed to and thermally contacted with the first heat discharge section; and the second fin module is socketed to and thermally contacted with the second heat discharge section.

This disclosure has the following effects. Since each first groove has a width greater than the width of each second groove, so that the liquefied working fluid can flow back to the heat receiving section more quickly. With the design of the straight edge of the heat receiving section and the heat discharge section, the thermal contact area between the thermal conduction base and each fin module is increased to improve the thermal conductivity. Since the capillary structure formed by each first groove and each second groove, its manufacture just requires a pipe reduction manufacture of each heat discharge section to form unequal widths, so that the manufacturing process can be simplified greatly.

### BRIEF DESCRIPTION OF THE DRAWINGS

FIG. 1 is a perspective view of a heat sink of this disclosure;

FIG. 2 is an exploded view of a heat sink of this disclosure;

FIG. 3 is a perspective view of a heat pipe of this disclosure;

FIG. 4 is a cross-sectional view of a heat receiving section of a heat pipe of this disclosure;

FIG. 5 is a cross-sectional view of a heat discharge section of a heat pipe of this disclosure;

FIG. 6 is a perspective view of a heat pipe in accordance with another embodiment of this disclosure;

FIG. 7 is a perspective view of a cooling device of this disclosure;

FIG. 8 is a perspective view of a cooling device in accordance with another embodiment of this disclosure; and

FIG. 9 is a cross-sectional view of a part of FIG. 8.

### DESCRIPTION OF THE PREFERRED EMBODIMENTS

The technical contents of this disclosure will become apparent with the detailed description of preferred embodiments accompanied with the illustration of related drawings as follows. It is intended that the embodiments and figures disclosed herein are to be considered illustrative rather than restrictive.

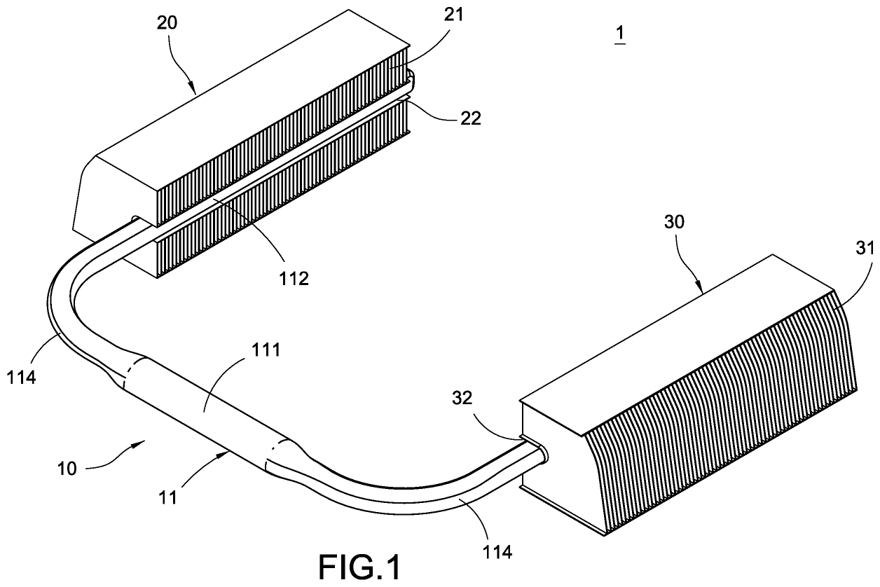

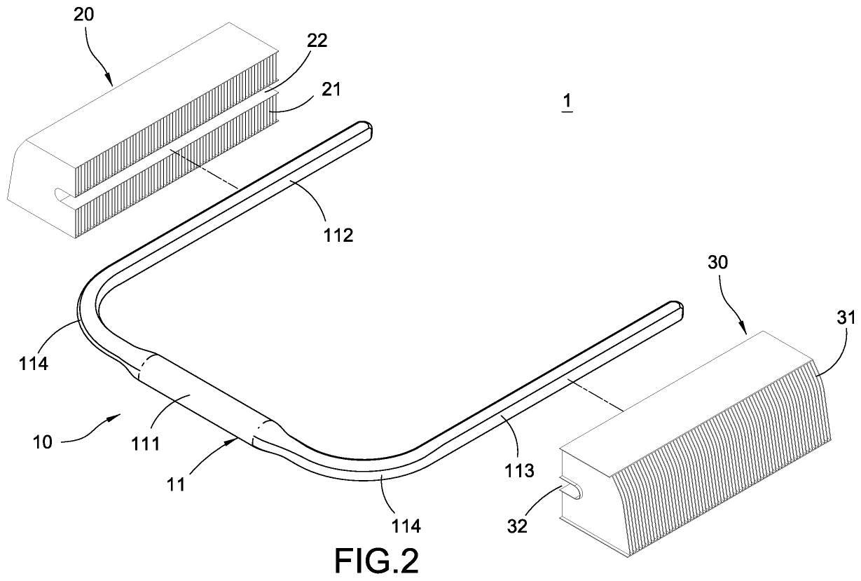

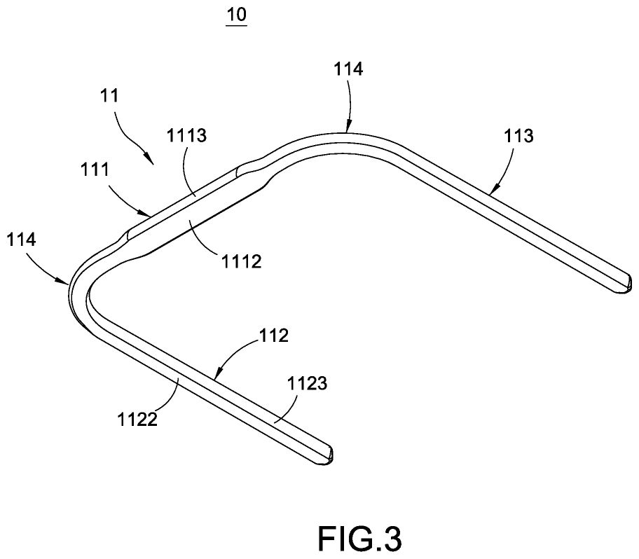

With reference to FIGS. 1 to 5 for a heat sink of this disclosure, the heat sink 1 comprises a heat pipe 10, a first fin module 20 and a second fin module 30.

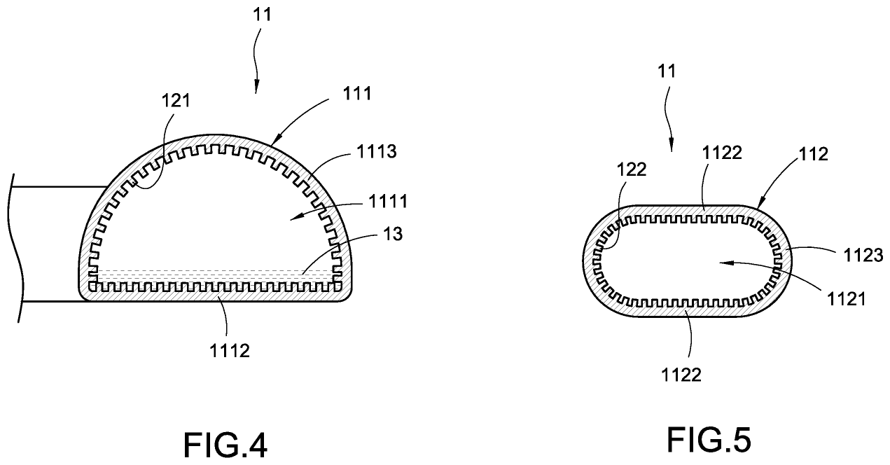

The heat pipe 10 comprises a pipe body 11 and a capillary structure and a working fluid 13 disposed inside the pipe body 11, and the heat pipe 10 has a heat receiving section 111 and a first heat discharge section 112 and a second heat discharge section 113 extending from both ends of the heat receiving section 111 respectively, and the heat receiving section 111 has a heat receiving chamber 1111 therein, and the first heat discharge section 112 and the second heat discharge section 113 have a heat discharge chamber 1121, 1131 therein separately, and the heat receiving chamber 1111 has a cross-sectional area greater than the cross-sectional area of each heat discharge chamber 1121, 1131. In other words, the heat receiving section 111 has a pipe size greater than the pipe size of the first heat discharge section 112 and the second heat discharge section 113.

Wherein, the cross-section of the heat receiving section 111 is comprised of a straight edge 1112 and a semicircular edge 1113 extending from both ends of the straight edge 1112 separately, and the capillary structure comprises a plurality of first grooves 121 and a plurality of second grooves 122 (as shown in FIGS. 4 and 5), and each first groove 121 is an inner wall formed at the straight edge 1112 and the semicircular edge 1113.

The first heat discharge section 112 is in a flat shape, and its cross-section is comprised of a pair of straight edges 1122 and a pair of semicircular edges 1123 extending from both ends of each straight edge 1122 respectively, wherein each second groove 122 is formed on the inner walls of each straight edge 1122 and each semicircular edge 1123; and each first groove 121 of the heat receiving section 111 has a width greater than the width of each second groove 122 of the first heat discharge section 112. Similarly, the second heat discharge section 113 and the shape of the internal structure are in the same shape as the first heat discharge section 112.

Further, the heat pipe 10 comprises an insulated section 114 disposed between the heat receiving section 111 and the first heat discharge section 112. Similarly, the insulated section 114 may be disposed between the heat receiving section 111 and the second heat discharge section 113, or an insulated section 114 is formed between the heat receiving section 111 and the first heat discharge section 112, and between the heating receiving section 111 and the second heat discharge section 113. In this embodiment, the cross-sectional shape of the insulated section 114 is a flat shape.

The first fin module 20 is formed by stacking and combining a plurality of cooling fins 21, and each respective cooling fin 21 has a slot 22 formed on a lateral side of the cooling fin 21, and the first fin module 20 is socketed to and thermally contacted with the first heat discharge section 112 through the slot 22.

The second fin module 30 is formed by stacking and combining a plurality of cooling fins 31, and a corresponding slot 32 is formed on a lateral side of each cooling fin 31, and the second fin module 30 is socketed to and thermally contacted with the second heat discharge section 113 by the slot 32.

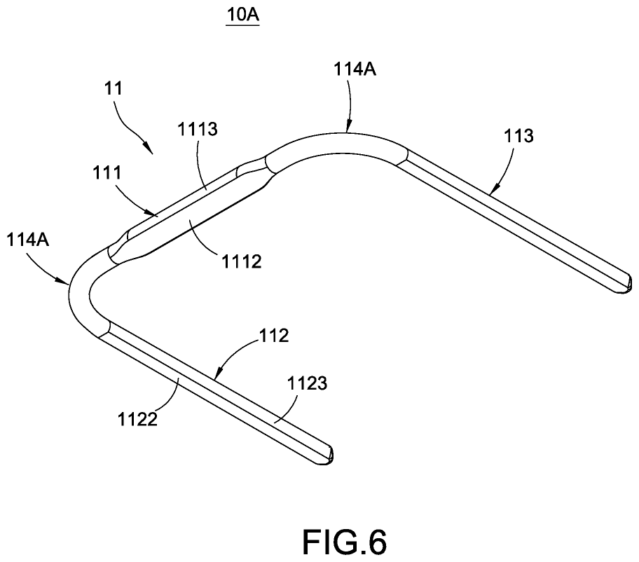

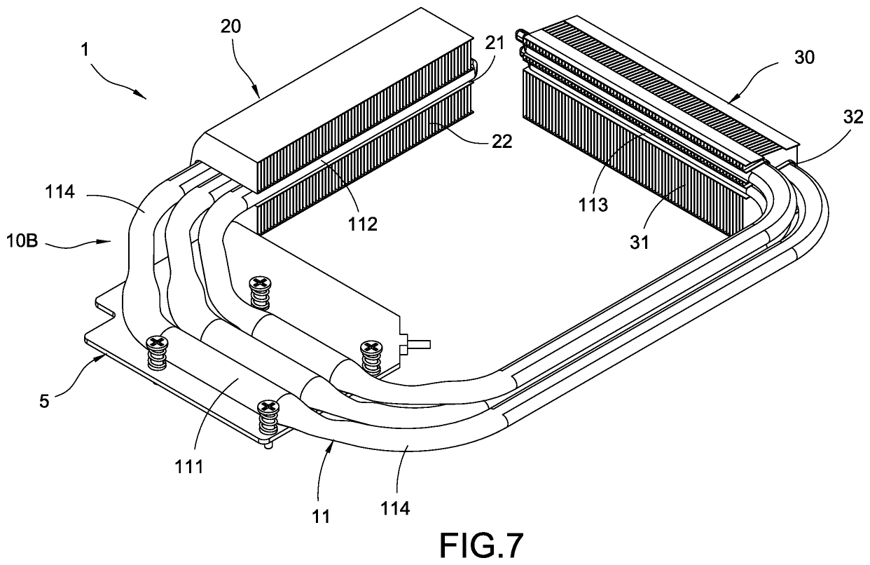

With reference to FIG. 6 for a heat pipe 10A of this embodiment, the difference between the heat pipe 10A of this embodiment and the heat pipe 10 of the previous embodiment resides on that the cross-sectional shape of each insulated section 114A of this embodiment is a circular shape.

With reference to FIG. 7 for another cooling device of this disclosure, the cooling device comprises a thermal conduction base 5 and a heat sink 1, and the heat sink 1 of this embodiment comprises a plurality of heat pipes 10B, a first fin module 20 and a second fin module 30, wherein each heat pipe 10B, the first fin module 20 and the second fin module 30 have characteristics substantially similar to those of each previous embodiment, and thus will not be repeated. Wherein, the thermal conduction base 5 is a vapor chamber, and the straight edge 1112 of the heat receiving section 111 of each heat pipe 10B is attached flatly onto the thermal conduction base 5, and the first heat discharge section 112 of each heat pipe 10B is passed, coupled and thermally contacted with the first fin module 20, and the second heat discharge section 113 of each heat pipe 10B is passed, coupled and thermally contacted with the second fin module 30.

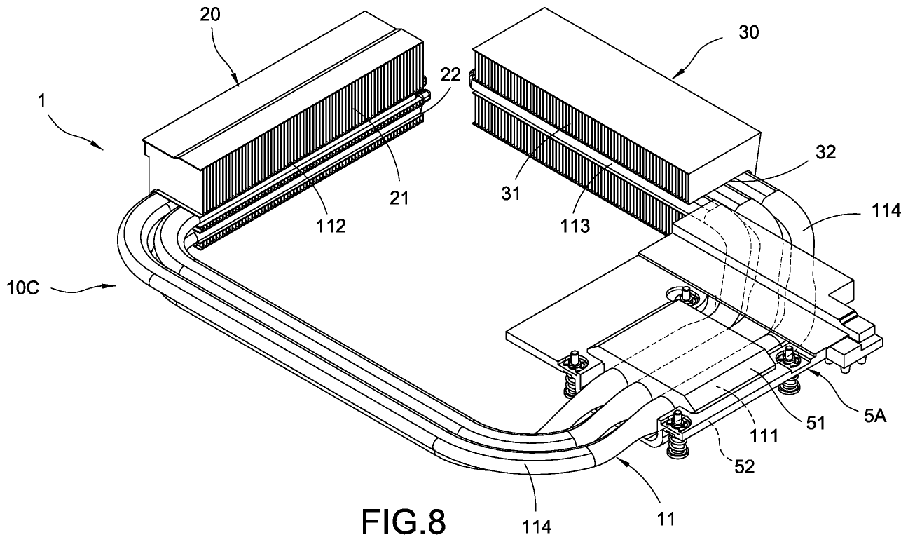

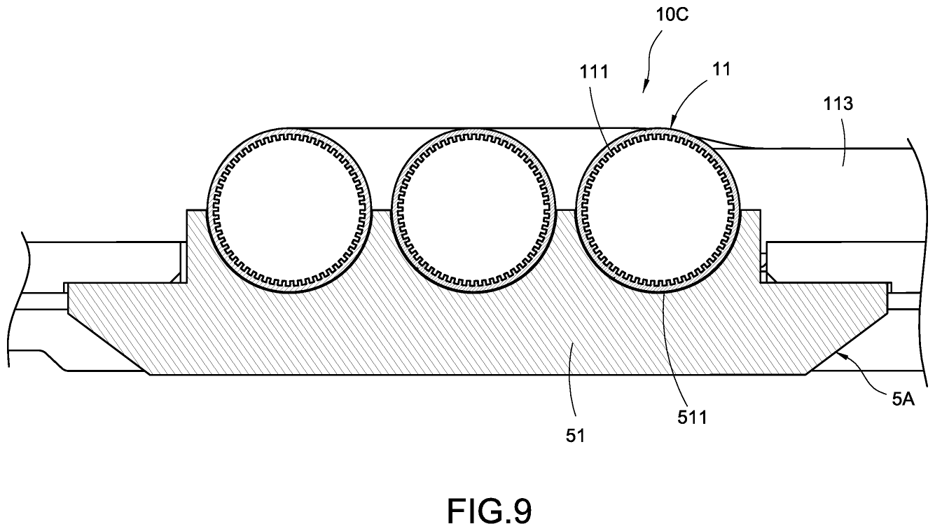

With reference to FIGS. 8 and 9 for the thermal conduction base 5A of this embodiment, the thermal conduction base 5A comprises a thermal conduction block 51 and a fixing plate 52, wherein the thermal conduction block 51 is made of copper, aluminum, or their alloys, and the thermal conduction block 51 has a plurality of channels 511, and each channel 511 is in a semicircular shape. Wherein, the cross-sectional shape of the heat receiving section 111 of each heat pipe 10C is a circular shape, and each heat receiving section 111 is configured to be corresponsive to each respective channel 511 and combined by the fixing plate 52.

While this disclosure has been described by means of specific embodiments, numerous modifications and variations could be made thereto by those skilled in the art without departing from the scope and spirit of this disclosure set forth in the claims.

What is claimed is:

1. A heat sink, comprising:
a heat pipe, comprising a pipe body, a capillary structure, and a working fluid filled in the pipe body, and the heat pipe including a heat receiving section, a first heat discharge section and a second heat discharge section extending from both ends of the heat receiving section respectively, a heat receiving chamber formed inside the heat receiving section, and a heat discharge chamber formed inside the first heat discharge section and the second heat discharge section separately, and the heat receiving chamber having a cross-sectional area greater than the cross-sectional area of each of the heat discharge chambers; a first fin module, socketed to and thermally contacted with the first heat discharge section; and
a second fin module, socketed to and thermally contacted with the second heat discharge section.

2. The heat sink of claim 1, wherein the heat receiving section has a pipe size greater than the pipe size of the first heat discharge section and the pipe size of the second heat discharge section.

3. The heat sink of claim 1, wherein the capillary structure comprises a plurality of first grooves and a plurality of second grooves, and each of the first grooves is formed inside the heat receiving section, and each of the second grooves is formed inside the first heat discharge section and the second heat discharge section separately, and the first groove has a width greater than the width of the second groove.

4. The heat sink of claim 1, wherein the cross-section of the heat receiving section includes a straight edge and a semicircular edge extending from both ends of the straight edge.

5. The heat sink of claim 1, wherein the cross-sectional shape of the heat receiving section is a circular shape.

6. The heat sink of claim 1, wherein the cross-section of the first heat discharge section comprises a pair of straight edges and a pair of semicircular edges extending from both ends of each of the straight edges to constitute a flat shape.

7. The heat sink of claim 1, wherein the heat pipe further comprises two insulated sections, and one of the insulated sections is disposed between the heat receiving section and the first heat discharge section, and the other insulated section is disposed between the heat receiving section and the second heat discharge section.

8. The heat sink of claim 7, wherein the cross-sectional shape of the insulated section is a flat shape or a circular shape.

9. The heat sink of claim 1, wherein the first fin module is formed by stacking and combining a plurality of cooling fins, and each of the cooling fins has a corresponding slot, and the first fin module is socketed to the first heat discharge section thorough each respective slot.

10. The heat sink of claim 1, wherein the second fin module is formed by stacking and combining a plurality of cooling fins, and each of the cooling fins has a corresponding slot and the second fin module is socketed to the first heat discharge section through each respective slot.

11. A cooling device, comprising:
a thermal conduction base; and
a heat sink, comprising a heat pipe, a first fin module and a second fin module, and the heat pipe including a pipe body and a capillary structure and a working fluid disposed inside the pipe body, and the heat pipe having a heat receiving section, and a first heat discharge section and a second heat discharge section extending from both ends of the heat receiving section respectively, and the heat receiving section being disposed on the thermal conduction base, and the heat receiving section having a heat receiving chamber therein, and the first heat discharge section and the second heat discharge section having a heat discharge chamber disposed therein separately, and the heat receiving chamber having a cross-sectional area greater than the cross-sectional area of each of the heat discharge chambers; and the first fin module being socketed to and thermally contacted with the first heat discharge section; and the second fin module being socketed to and thermally contacted with the second heat discharge section.

12. The cooling device of 11, wherein the thermal conduction base is a vapor chamber.

13. The cooling device of 11, wherein the heat sink comes with a plurality of heat pipes.

14. The cooling device of 13, wherein the thermal conduction base comprises a thermal conduction block and a fixing plate, and the thermal conduction block has a plurality of channels for accommodating the heat pipes respectively, and the fixing plate and the thermal conduction block jointly clamp each of the heat pipes.

15. The cooling device of 11, wherein the heat receiving section has a pipe size greater than the pipe size of the first heat discharge section and the pipe size of the second heat discharge section.

16. The cooling device of 11, wherein the capillary structure includes a plurality of first grooves and a plurality of second grooves, and each of the first grooves is formed inside the heat receiving section, and each of the second grooves is formed inside the first heat discharge section and the second heat discharge section, and the first groove has a width greater than the width of the second groove.

17. The cooling device of 11, wherein the cross-section of the heat receiving section includes a straight edge and a semicircular edge extending from both ends of the straight edge.

18. The cooling device of 11, wherein the cross-sectional shape of the heat receiving section is a circular shape.

19. The cooling device of 11, wherein the cross-section of the first heat discharge section includes a pair of straight edges and a pair of semicircular edges extending from both ends of each of the straight edges to constitute a flat shape.

20. The cooling device of 11, wherein the heat pipe further comprises two insulated sections, and one of the insulated sections is disposed between the heat receiving section and the first heat discharge section, and the other insulated section is disposed between the heat receiving section and the second heat discharge section, and the cross-sectional shape of the insulated section is a flat shape or a circular shape.
